(19) United States
(12) Patent Application Publication
(10) Pub. No.: US 2025/0337377 A1
(43) Pub. Date: Oct. 30, 2025

(54) FULLY DIFFERENTIAL QUADRATURE DRIVER

(71) Applicant: STMicroelectronics International N.V., Geneva (CH)

(72) Inventors: Pavan Nallamothu, Little Elm, TX (US); Milad Alwardi, Allen, TX (US); Deyou Fang, Frisco, TX (US); Marco Garbarino, Cusago (IT); Yamu Hu, Allen, TX (US); David McClure, Carrollton, TX (US); Alberto Giuseppe Cavallaro, Catania (IT)

(21) Appl. No.: 18/644,927

(22) Filed: Apr. 24, 2024

(51) Int. Cl. H03D 3/00; G01C 19/72; H03D 3/18; H03D 3/24

(52) U.S. Cl. CPC H03F 3/45; G01C 19/726

(57) ABSTRACT

According to an embodiment, a circuit for quadrate error correction is proposed. The circuit includes a set of first resistors receiving a demodulated low-voltage differential signal from gyroscope sense electrodes; an ICMFB circuit with adjustable current sinks maintaining a low-voltage input level by controlling current; an HV driver circuit creating a high-voltage differential output from the low-voltage input, supplied to gyroscope correction electrodes; a set of second resistors where the input-to-output differential gain is defined by their relative resistances; and an output common-mode feedback circuit adapting the high-voltage output to a low-voltage for the HV driver.

### TECHNICAL FIELD

The present disclosure generally relates to analog control system and, in particular embodiments, to a fully differential quadrature driver.

### BACKGROUND

Quadrature error is a significant challenge when working with Micro-Electrical Systems (MEMS), specifically devices that contain drive and sense axes, such as a MEMS gyroscope. The problem arises when the drive and sense axes are not perfectly orthogonal during manufacturing, leading to unintended non-orthogonal motion in the sense direction due to the motion of the drive component.

An uncontrolled quadrature error degrades the performance of the gyroscope. It increases the design requirements of other blocks in the system as it amplifies the effects due to phase error and phase jitter. These errors compromise numerous aspects, including the integrity of the rate signal, zero rate outputs (ZRO) baseline stability, ZRO drift resilience, noise levels, and vibration immunity. As such, it places arduous design constraints on other components in the signal processing chain to compensate for these issues.

### SUMMARY

Technical advantages are generally achieved by embodiments of this disclosure, which describe a fully differential quadrature driver.

A first aspect relates to a circuit for correcting a quadrature error in a gyroscope. The circuit comprising: a pair of first resistors configured to receive a differential input low-voltage signal, a differential value of the differential input low-voltage signal set based on a demodulated quadrature signal measured by sense electrodes of the gyroscope; an input common-mode feedback (ICMFB) circuit coupled to the pair of first resistors, the ICMFB circuit comprising a pair of adjustable current sinks configured to regulate an input common-mode of the circuit at a low-voltage level by managing current flowing through the adjustable current sinks; a high-voltage (HV) driver circuit configured to provide a differential output high-voltage signal based on the differential input low-voltage signal, the differential output high-voltage signal being fed to quadrature correction electrodes of the gyroscope to correct the quadrature error; a pair of second resistors, wherein a differential gain between the input differential input low-voltage signal and the differential output high-voltage signal is determined by a relative resistance values of the pair of first resistors and pair of second resistors; and an output common-mode feedback circuit configured to convert a high-voltage common-mode output of the circuit to a low-voltage level suitable for the HV driver circuit.

A second aspect relates to system for correcting a quadrature error in a gyroscope, the system comprising: a digital control circuit configured to generate a differential input low-voltage signal based on a demodulated quadrature signal from sense electrodes of the gyroscope; and a low-voltage to high-voltage (LV-to-HV) differential translator circuit, the LV-to-HV differential translator circuit comprising: a pair of first resistors configured to receive the differential input low-voltage signal, an input common-mode feedback (ICMFB) circuit coupled to the pair of first resistors, the ICMFB circuit comprising a pair of adjustable current sinks configured to regulate an input common-mode of the LV-to-HV differential translator circuit at a low-voltage level by managing current flowing through the adjustable current sinks, a high-voltage (HV) driver circuit configured to provide a differential output high-voltage signal based on the differential input low-voltage signal, the differential output high-voltage signal being fed to quadrature correction electrodes of the gyroscope to correct the quadrature error, a pair of second resistors, wherein a differential gain between the input differential input low-voltage signal and the differential output high-voltage signal is determined by a relative resistance values of the pair of first resistors and pair of second resistors, and an output common-mode feedback circuit configured to convert a high-voltage common-mode output of the LV-to-HV differential translator circuit to a low-voltage level suitable for the HV driver circuit.

A third aspect relates to a system to correct a quadrature error in a gyroscope, the system comprising: a digital control circuit configured to generate a differential input low-voltage signal based on a demodulated quadrature signal from sense electrodes of the gyroscope; and a low-voltage to high-voltage (LV-to-HV) differential translator circuit configured to receive the differential input low-voltage signal and generate a differential output low-voltage signal for quadrature correction electrodes of the gyroscope to correct the quadrature error, the LV-to-HV differential translator circuit comprising: an input common-mode feedback (ICMFB) circuit configured to regulate an input common-mode of the LV-to-HV differential translator circuit at a low-voltage level, a high-voltage (HV) driver circuit configured to provide the differential output high-voltage signal based on the differential input low-voltage signal, and an output common-mode feedback circuit configured to convert a high-voltage common-mode output of the LV-to-HV differential translator circuit to a low-voltage level suitable for the HV driver circuit.

Embodiments can be implemented in hardware, software, or any combination thereof.

### BRIEF DESCRIPTION OF THE DRAWINGS

For a more complete understanding of the present disclosure and the advantages thereof, reference is now made to the following descriptions taken in conjunction with the accompanying drawings, in which:

FIG. 1 is a Micro-Electro-Mechanical Systems (MEMS) gyroscope;

FIG. 2 is a block diagram of an embodiment system;

FIG. 3 is a block diagram of an embodiment MEMS gyroscope with quadrature error correction electrodes;

FIG. 4 is a block diagram of an embodiment system 400;

FIG. 5 is a schematic of an embodiment low-voltage to high-voltage (LV-to-HV) differential translator circuit; and

FIG. 6 is a schematic of an embodiment high-voltage (HV) driver circuit.

### DETAILED DESCRIPTION OF ILLUSTRATIVE EMBODIMENTS

This disclosure provides many applicable inventive concepts that can be embodied in a wide variety of specific contexts. The particular embodiments are merely illustrative of specific configurations and do not limit the scope of the claimed embodiments. Features from different embodiments may be combined to form further embodiments unless noted otherwise. Various embodiments are illustrated in the accompanying drawing figures, where identical components and elements are identified by the same reference number, and repetitive descriptions are omitted for brevity.

Variations or modifications described in one of the embodiments may also apply to others. Further, various changes, substitutions, and alterations can be made herein without departing from the spirit and scope of this disclosure as defined by the appended claims.

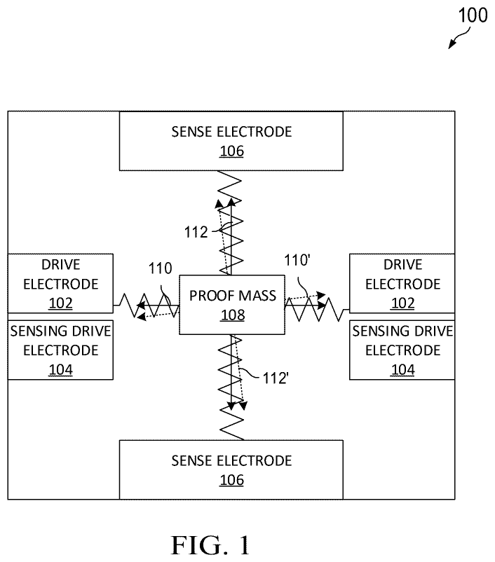

FIG. 1 illustrates a Micro-Electro-Mechanical Systems (MEMS) gyroscope 100. MEMS gyroscope 100 includes a pair of drive (D) electrodes 102, a pair of sense drive (SD) electrodes 104, a pair of sense (S) electrodes 106, and a proof mass 108. MEMS gyroscope 100 is configured to measure the rotation rate by exploiting the Coriolis effect.

The drive (D) electrodes 102 set the proof mass 108 into oscillatory motion. They accomplish this by applying an alternating voltage or an electrostatic force to the proof mass 108, causing it to vibrate at a natural or a resonant frequency along the drive axis 110. This vibration is necessary to create the conditions under which the Coriolis force can be observed and measured. Without this consistent and controlled motion, detecting angular rotation based on the Coriolis effect would not be possible.

The sense drive (SD) electrodes 104 detect changes in the vibration of the proof mass 108 due to the drive motion. This detection can be used in feedback control systems where constant oscillation amplitude is necessary for accurate measurements.

The proof mass 108, a vibrating structure, oscillates along the drive axis 110. When the MEMS gyroscope 100 experiences rotation about the sense axis 112, which, in an ideal MEMS gyroscope, is perpendicular to the drive axis 110, the Coriolis force comes into play. This force results from the rotation and acts perpendicular to the drive axis 110 and the sense axis 112, causing the proof mass 108 to deflect.

Due to the Coriolis force, the mass deflection perpendicular to the rotation and the drive axis alters the capacitance between the proof mass 108 and the sense (S) electrodes 106, which can be read as a Coriolis signal indicative of the rotational rate.

The raw Coriolis signal contains valuable information about the rotation rate but requires processing to isolate and extract this information. Through demodulation, which typically involves filtering and amplification, the raw signal is refined to produce what is known as the rate signal. The rate signal represents the device's rotational rate and is a clean measurement of how fast and in what direction the MEMS gyroscope 100 is rotating. The processing removes unwanted components at the drive frequency and other noise, ensuring an accurate portrayal of angular velocity.

As noted, in an ideal MEMS gyroscope, the drive axis 110 is perpendicular to the sense axis 112. However, due to various imperfections during manufacturing, the drive axis 110′ is not perfectly perpendicular to the sense axis 112 in a real MEMS gyroscope. The angular imperfection between the two axes leads to quadrature leakage in the sense direction due to the motion of the drive component. The non-orthogonal motion results in an undesirable quadrature error.

Generally, the quadrature error manifests as a signal 90 degrees out of phase with the Coriolis signal and is several orders larger than the rate signal. Without correction, this quadrature error leads to erroneous outputs known as zero rate outputs (ZRO), ZRO drift, and additional noise within the rate signal. A correction force becomes necessary to counteract the quadrature error, dependent on the common and differential modes applied to the quadrature electrodes. This force is tuned in relation to the voltage of the MEMS rotor.

Conventional solutions to rectify the quadrature error typically involve using two high-voltage, single-ended signals. These signals are applied to the quadrature electrodes to counteract the differential quadrature error. However, this approach has several limitations. The range of common and differential mode voltages that can be used effectively is constrained, limiting the correction's flexibility and applicability. Further, because the differential signal is created by utilizing two separate single-ended drivers, there is a deterioration in the power supply rejection ratio (PSRR) and common mode rejection ratio (CMRR). This degradation can reduce the MEMS device's overall performance as it becomes more susceptible to fluctuations in power supply and interference that may affect the common mode signal.

This disclosure aims to counteract the quadrature error in a MEMS device. In embodiments, this is achieved using a high-voltage (HV) driver capable of differential output. The driver features programmable output settings for common mode voltage, allowing adjustments in the common mode level and control differential voltage to reduce quadrature error. Flexibility in Shifting the common mode level and differential mode enables precise control and cancellation of the quadrature error. These and additional details are further detailed below.

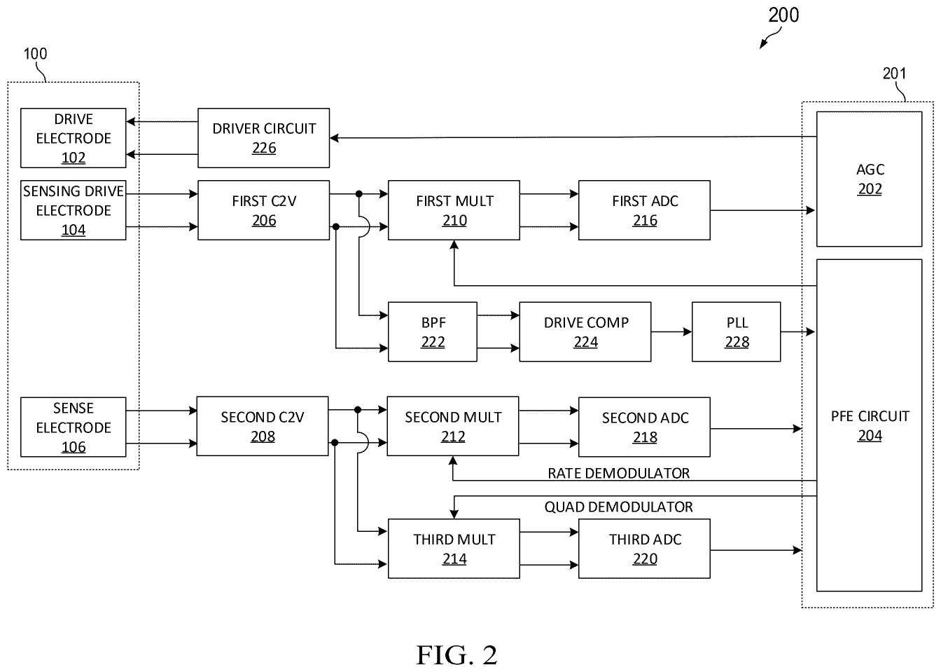

FIG. 2 illustrates a block diagram of an embodiment system 200. System 200 includes the MEMS gyroscope 100, a digital circuit 201 that includes an automatic gain control (AGC) circuit 202 and a phase frequency extractor (PFE) circuit 204, a first charge-to-voltage (C2V) converter 206, a second C2V converter 208, a first multiplier 210, a second multiplier 212, a third multiplier 214, a first analog-to-digital converter (ADC) 216, a second ADC 218, a third ADC 220, a band-pass (BP) filter 222, a drive comparator 224, a driver circuit 226, and a phase-locked loop (PLL) circuit 228, which may (or may not) be arranged as shown. System 200 may include additional components that are not shown. For example, the digital circuit 201 may include a controller that receives the measurements from the second ADC 218 and the third ADC 220.

AGC circuit 202 is configured to regulate the amplitude of oscillations of the proof mass 108 in the MEMS gyroscope 100 to maintain the precision of the measurements. AGC circuit 202 produces a digital control signal to the driver circuit 226. The driver circuit 226 generates an analog differential control signal from the digital control signal. The analog differential control signal is fed to the drive (D) electrodes 102 of the MEMS gyroscope 100 to control the oscillation of the proof mass 108.

The sense drive (SD) electrodes 104 detect variations in the oscillation amplitude of the proof mass 108 caused by the drive motion. The detected changes are used for the feedback control mechanisms to sustain a constant oscillation amplitude, ensuring accurate and consistent measurements from the MEMS gyroscope 100.

The analog signal from the sense drive (SD) electrodes 104, representing the detected changes, is directed to the first C2V converter 206. First C2V converter 206 is configured to transform the analog charge signal into an equivalent voltage signal that is more suitable for subsequent electronic processing.

Following conversion, the voltage signal output from the first C2V converter 206 is supplied to the first multiplier 210. Concomitantly, the first multiplier 210 receives a second input, a digital signal from the FD circuit 204. FD circuit 204 alters the reference signal frequency to align it with the operational needs of system 200.

The first multiplier 210 blends the two signals—the converted voltage from the first C2V converter 206 and the digital signal from the FD circuit 204—to produce an output that carries information about the motion of the proof mass 108.

The product signal from the first multiplier 210 is conveyed to the first ADC 216. The first ADC 216 is configured to digitize the analog signal from the first multiplier 210 so that digital circuits can process it. The digital output from the first ADC 216 is provided to the AGC circuit 202 as part of a feedback control loop.

Within this feedback loop, the AGC circuit 202 analyzes the digital information given by the first ADC 216 to gauge whether adjustments are necessary. If so, the AGC circuit 202 modifies its digital output to the driver circuit 226 accordingly, creating a closed-loop system that maintains stable and precise control over the vibration amplitude of the drive (D) electrodes 102. This closed-loop system ensures that the MEMS gyroscope 100 functions with a high degree of accuracy.

To ensure the high precision and stability of the MEMS gyroscope 100 across different processes and temperatures throughout its lifespan, it is advantageous to operate it at resonance while maintaining a tightly controlled drive amplitude. Correcting any quadrature error present in system 200 allows for obtaining a dependable rate signal. The valuable data regarding this is encapsulated within the sine wave output produced by the sense (S) electrodes 106. This sine wave must undergo demodulation and be digitized for further use.

The sense drive (SD) electrodes 104 demodulated the amplitude information by a change in capacitance. The amplitude of this waveform is directly proportional to the drive applied to the MEMS gyroscope 100, and its frequency matches the resonance frequency (Fa) of the MEMS drive. The output of the first C2V converter 206 is additionally provided to the band-pass filter 222. The band-pass filter 222 is configured to eliminate the DC component-such as offsets—and any high-frequency signals that may be superimposed on top of resonance frequency (Fa). After this filtering stage, the drive comparator 224 transforms the sine wave into a square wave at the same resonance frequency (Fa). The square wave resonance frequency (Fa) is the input for the PLL circuit 228. PLL circuit 228 is configured to generate multiples of the resonance frequency (Fa), which are then utilized by the FD circuit 204 to create demodulation signals.

The analog sine wave from the sense drive (SD) electrodes 104, which flags variable amplitude based on whether the MEMS gyroscope 100 is in startup or normal mode and is accompanied by higher order harmonics of the resonance frequency (Fa), as well as noise, is transformed into a square wave by the drive comparator 224. The drive comparator 224 generates the square wave signal at the resonance frequency (Fa) by processing the input differential sine wave. The drive comparator 224 is designed to be high-speed to prevent the propagation delay from causing any demodulation errors-such discrepancies are typically addressed during production trimming to ensure that they do not contribute to further errors over the operational life of the MEMS gyroscope 100.

False transitions caused by input noise can produce incorrect resonance frequency (Fd) pulses, compromising the precision required for proper demodulation. Comparator hysteresis is set during production to negate the potential effects of the higher-order resonance frequency (Fd) and any noise superimposed on the resonance frequency (Fd) sine signal. System 200 can effectively reject unwanted signals by programming the parameter at the manufacturing stage, ensuring the MEMS gyroscope 100 functions correctly.

The demodulation signals from the FD circuit 204 are applied to the first multiplier 210 in the path of the sense drive (SD) electrode, and the second multiplier 212 and the third multiplier 214 in the path of the sense (S) electrode.

The demodulation signal for the sense drive (SD) electrodes 104 is the resonance frequency (Fd), which is fed into the feedback control loop at the first multiplier 210. This allows the AGC circuit 202 to provide a digital signal to the driver circuit 226 and keep the MEMS gyroscope 100 tuned to its resonant frequency and at the desired amplitude level.

The sense (S) electrodes 106 carries information about the rate of movement and the quadrature-phase, necessitating demodulation by an appropriate phase signal to extract this information. The demodulated rate signal (RATE_{S}) for the sense (S) electrodes 106 takes the form of a cosine function (RATE_{S}=cos ((ω_{d})t), where ω_{d} is the angular drive frequency of the MEMS gyroscope 100. The demodulated rate signal (RATE_{S}) for the sense (S) electrodes 106 indicates angular velocity. It is provided as an input for the second multiplier 212. A second input of the second multiplier 212 is the output of the sense (S) electrodes 106. The output of the second multiplier 212 is fed to the second ADC 218 as a digital signal indicating the rate signal.

The demodulated quadrature signal (QUAD_{S}) for the sense (S) electrodes 106 takes the form of a sine function (QUAD_{S}=sind((ω_{d})t)). The demodulated quadrature signal (QUAD_{S}) for the sense (S) electrodes 106 is used to evaluate and correct the quadrature errors within the MEMS gyroscope 100, contributing to a stable Zero Rate Level (ZRL) and minimizing rate noise. The demodulated quadrature signal (QUAD_{S}) is provided as an input to the third multiplier 214. A second input of the third multiplier 214 is the output of the sense (S) electrodes 106. The output of the third multiplier 214 is fed to the third ADC 220 as a digital signal indicating the quadrature error.

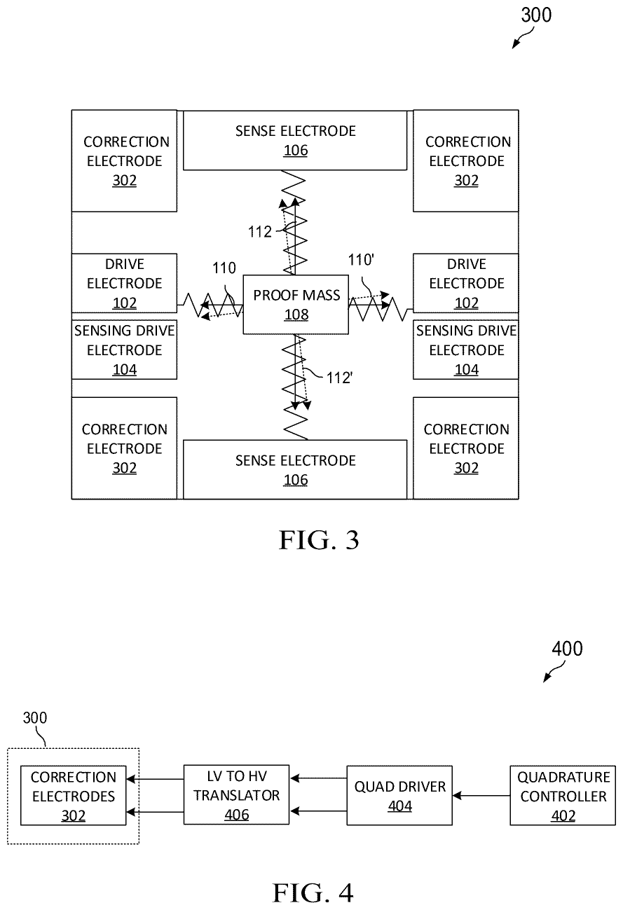

FIG. 3 illustrates a block diagram of an embodiment MEMS gyroscope 300 with quadrature error correction electrodes. The structure of the MEMS gyroscope 300 is similar to the MEMS gyroscope 100 with an additional set of correction electrodes 302. Similar components in the two figures are not discussed for the sake of brevity of discussion.

In embodiments, the correction electrodes 302 may be capacitive, resistive loads, or a combination thereof. Correction electrodes 302 are configured to mitigate the quadrature error in MEMS gyroscope 300. They are not used to detect or measure rotation but to nullify or cancel out the unwanted quadrature error to improve the accuracy of the MEMS gyroscope 300.

Correction electrodes 302 operate after detecting capacitive changes associated with the quadrature motion through the sense (S) electrodes 106. Once this motion is identified, a corrective feedback mechanism is engaged.

The feedback mechanism typically generates a compensation signal tuned to offset the detected quadrature error. The signal is applied as a voltage to the correction electrodes 302, which create electrostatic forces to counteract the unwanted quadrature motion upon the proof mass 108. The magnitude and phase of the compensation signal can be adjusted through a manual tuning process or with an automated control system, which could be either open-loop or closed-loop.

Typically, correction electrodes 302 are operated in pairs to create differential electrostatic forces through the application of voltages. For example, a first voltage (V_{Q1}) may be applied to one of the correction electrodes 302 in a pair to create an attractive force, while a second voltage (V_{Q2}) is applied—which can be of opposite polarity to create a repulsive force or a different magnitude of an attractive force—to the other one of the correction electrodes 302 in the pair. The differential voltage applied to the pair of correction electrodes 302 is represented as: (V_{Q1}−V_{Q2}), whereas the common-mode voltage applied to the pair of correction electrodes 302 is represented as (V_{Q1}+V_{Q2})/2.

The electrostatic force (F_{QC}) can be represented by the equation,

$${F}_{QC} \approx [ {V}_{ROT} - \frac{( {V}_{Q 1} + {V}_{Q 2} )}{2} ] \times ( {V}_{Q 1} - {V}_{Q 2} ) ,$$

where V_{ROT} is the rotor voltage. The rotor voltage is an electric potential applied to the proof mass 108.

The continuous cancellation of quadrature error with high precision becomes advantageous for the high-fidelity operation of the MEMS gyroscope 300. This cancellation is maintained over the product's entire lifetime while accommodating variations in manufacturing processes and temperature changes.

FIG. 4 illustrates a block diagram of an embodiment system 400, which may be used with system 200 to operate the MEMS gyroscope 300. System 400 includes the MEMS gyroscope 300, a quadrature controller 402, a quadrature driver 404, and a low-voltage to high-voltage (LV-to-HV) differential translator circuit 406, which may (or may not) be arranged as shown. System 400 may include additional components not shown. In embodiments, the quadrature controller 402 is implemented within the digital circuit 201. In embodiments, the quadrature controller 402 receives the digital signal indicating the quadrature error from the output of the third ADC 220 as part of a closed-loop feedback system for adjusting the quadrature error.

Based on the digital signal from the third ADC 220 indicating the MEMS gyroscope's quadrature error, the quadrature controller 402 provides a digital signal to the quadrature driver 404 to correct for the quadrature error through the correction electrodes 302.

The quadrature driver 404 generates a pair of low-voltage signals from the digital signal, a first voltage (V_{Q1_LV}) and a second voltage (V_{Q2_LV}). The LV-to-HV differential translator circuit 406 receives the low-voltage first voltage (V_{Q1_LV}) and the low-voltage second voltage (V_{Q2_LV}) and converts them to high-voltage differential signals, a first voltage (V_{Q1_HV}) and a second voltage (V_{Q2_HV}). The high-voltage differential signals are applied to a respective one of the pair of correction electrodes 302 to offset the detected quadrature error.

Conventionally, the voltages applied to the pair of the correction electrodes 302 have been single-ended. Disadvantageously, the single-ended signals limit the adjustment range of the common-mode voltage and the differential voltage of the electrostatic force (F_{QC}). Further, the system implementing a single-ended solution suffers from poor power supply rejection ratio (PSRR) and common mode rejection ratio (CMRR).

The proposed high-voltage differential signals at the output of the LV-to-HV differential translator circuit 406 allow for generating the common-mode voltage and the differential voltage of the electrostatic force (F_{QC}) in correlation with the rotor voltage. Further, LV-to-HV differential translator circuit 406 allows for low current consumption, minimal noise production, good power supply rejection ratio (PSRR), and high common mode rejection ratio (CMRR) compared to the single-ended conventional solution. Moreover, the differential signals generated by the LV-to-HV differential translator circuit 406 allow the flexibility in adjusting values of the common-mode voltage and the differential voltage of the electrostatic force (F_{QC}) to enable a broader range of quadrature errors to be effectively neutralized.

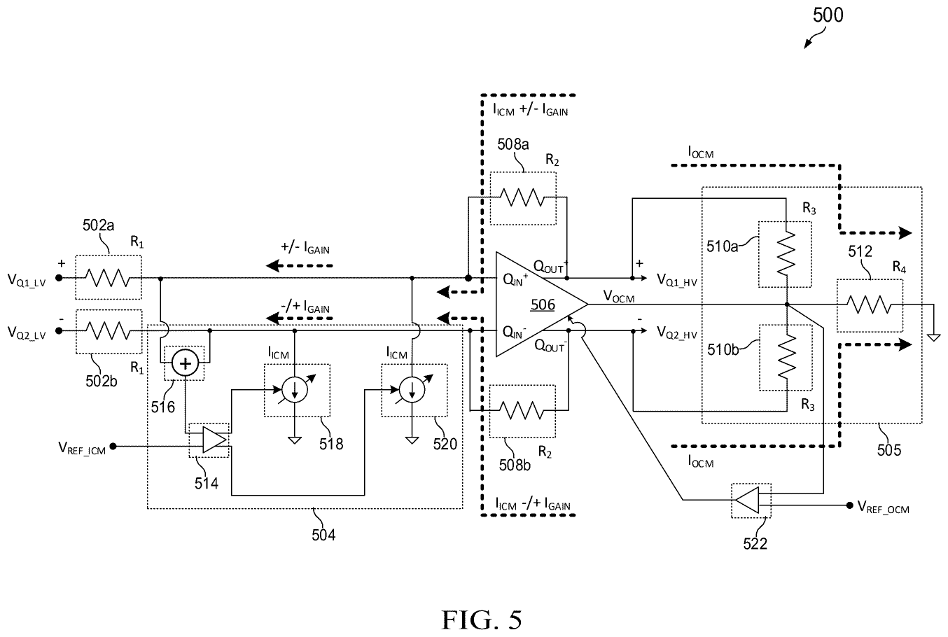

FIG. 5 illustrates a schematic of an embodiment low-voltage to high-voltage (LV-to-HV) differential translator circuit 500, which may be implemented as the LV-to-HV differential translator circuit 406. LV-to-HV differential translator circuit 500 includes a pair of first resisters (R₁) 502a-b, an input common-mode feedback (ICMFB) circuit 504, a high-voltage (HV) driver circuit 506, a pair of second resistors (R₂) 508a-b, an output common-mode feedback (OCMFB) circuit 505, and a first differential amplifier 522, which may (or may not) be arranged as shown. LV-to-HV differential translator circuit 500 may include additional components that are not shown.

In embodiments, the HV driver circuit 506 is implemented as a folded cascode operational amplifier with a class A output stage and common-mode feedback to support a fully differential architecture, its biases, and protection devices and diodes. The input voltages to the HV driver circuit 506 include input voltages (Q_{IN}⁺ and Q_{IN}⁻). The output voltages of the HV driver circuit 506 include output voltages (Q_{OUT}⁺ and Q_{OUT}⁻), which are provided to the correction electrodes 302 to offset the quadrature error.

High-voltage (HV) devices typically do not exhibit the best noise performance characteristics. They require a larger chip area and necessitate drawing current from a higher voltage source, such as a charge pump, which further increases the area consumed. By designing the first stage of the LV-to-HV differential translator circuit 500 with low-voltage (LV) components, noise is reduced alongside the benefits of conserving area and lowering power consumption.

In embodiments, the low-voltage domain is between 1.2 and 3.3 volts. In embodiments, the high-voltage domain is between greater than 5 volts.

The LV-to-HV differential translator circuit 500 is configured to receive the differential low-voltage, first voltage (V_{Q1_LV}) and second voltage (V_{Q2_LV}) and convert them to a differential high-voltage, first voltage (V_{Q1_HV}) and second voltage (V_{Q2_HV}).

The differential gain between the input voltages (V_{Q1_LV} and V_{Q2_LV}) and the output voltages (Q_{OUT}⁺ and Q_{OUT}⁻) is determined by the relative resistance values of the first resisters (R₁) 502a-b to the second resistors (R₂) 508a-b. The gain is defined by the current (I_{GAIN}) that flows from the output back to the circuit's input. The gain circuit boosts the low-voltage signal to high-voltage while maintaining a wide differential gain. Notably, the input side of the HV driver circuit 506 operates in the low voltage domain to achieve benefits such as lower power consumption, diminished noise and offset levels, reduced consumption of space on the chip (minimized area), and the important aspect of avoiding potential damage to the gate oxide that can occur as a result of exposure to excessive voltages.

In embodiments, the current (I_{GAIN}) is the microamps range for a typical low-power design. In an embodiment, the current (I_{GAIN}) is less than 1 microamp.

To isolate the input common-mode voltage (V_{ICM}) from fluctuations in the output common-mode voltage (V_{OCM}), the input common-mode feedback circuit 504 is introduced. The input common-mode feedback circuit 504 utilizes a regulated current to sustain a stable input common-mode voltage (V_{ICM}). Concurrently, the current (I_{GAIN}) establishes the circuit's gain, which is achieved relative to the differential output voltage across the output common-mode voltage (V_{OCM}). By including the input common-mode feedback circuit 504, variations in the output do not adversely affect the stability of the input common-mode voltage (V_{ICM}), thereby achieving a consistent performance of the input stage.

In embodiments, the input common-mode voltage (V_{ICM}) is between 1 and 1.6 volts. In an embodiment, the input common-mode voltage (V_{ICM}) is 1.3 volts.

In embodiments, the output common-mode voltage (V_{OCM}) is between 0.5 and 1.25 volts. In an embodiment, the output common-mode voltage (V_{OCM}) is 0.75 volts. In embodiments, the output common-mode voltage (V_{OCM}) can vary based on the quadrature common-mode requirement and the differential that must be applied.

The input common-mode feedback circuit 504 includes a second differential amplifier 514, an adder 516, a first adjustable current sink 518, and a second adjustable current sink 520, which may (or may not) be arranged as shown. The adder 516 combines the low-voltage, first voltage (V_{Qin+}) (i.e., the non-inverting signal of the differential input signal) and the low-voltage, second voltage (V_{Qin-}) (i.e., the inverting signal of the differential input signal) to provide as an input to the second differential amplifier 514, the input common-mode voltage (V_{ICM}) regulates the first voltage (V_{Qin+}) and the second voltage (V_{Qin-}) to second input of the second differential amplifier 514 is coupled to, for example, a voltage regulator or a bandgap source to provide a low-voltage reference voltage (V_{REF_ICM}). The difference between the reference voltage (V_{REF_ICM}) and the input common-mode voltage (V_{ICM}) is provided as input to the first adjustable current sink 518 and the second adjustable current sink 520 to adjust the input common-mode current (I_{ICM}) flowing through the second resistors (R₂) 508a-b.

In embodiments, the low-voltage reference voltage (V_{REF_ICM}) is between 1 and 1.6 volts. In an embodiment, the low-voltage reference voltage (V_{REF_ICM}) is 1.3 volts.

In embodiments, the value of the input common-mode current (I_{ICM}) depends on the selected input common-mode voltage (V_{ICM}). In embodiments, the input common-mode current (I_{ICM}) is the microamps range for a typical low-power design. In an embodiment, the input common-mode current (I_{ICM}) is less than one microamp.

The input common-mode feedback circuit 504 is configured to regulate the input common-mode at the low-voltage domain by managing the current flow through the adjustable current sinks. The controlled current is static and is responsible for establishing the input common-mode voltage. In its regulatory capacity, the input common-mode feedback circuit 504 adjusts the low-voltage input common mode and manages the input common-mode current (I_{ICM}) flowing through the second resistors (R₂) 508a-b, allowing for the appropriate level shifting of the common mode within the circuit.

In a fully differential architecture, an output common-mode feedback circuit is typically used to properly bias the output stage. In conventional systems, and contrast to the output common-mode feedback circuit 505, output common-mode feedback is achieved by sense the output common-mode voltage (V_{OCM}) and regulating it accordingly. In these systems, no current traverses through the pair of third resistors (R₃) 510a-b.

The first differential amplifier 522 has a first input coupled to the output common-mode voltage (V_{OCM}). A second input of the first differential amplifier 522 is coupled to a low-voltage reference voltage (V_{REF_OCM}). The difference between the reference voltage (V_{REF_OCM}) and the output common-mode voltage (V_{OCM}) is provided as input to HV driver circuit 506. Adjusting the reference voltage (V_{REF_OCM}) increases the operational latitude, allowing for a broader spectrum of differential and common-mode voltages applied to the pair of correction electrodes 302 to correct for the quadrature error. The operational range for this system is carefully selected, considering the rotor voltage and the high-voltage (HV) supply, to ensure the system 400 functions effectively within its intended parameters.

The output common-mode feedback circuit 505 includes a pair of third resistors (R₃) 510a-b and a fourth resistor (R₄) 512, which interact with the reference voltage (V_{REF_OCM}) to regulate the output common-mode voltage (V_{OCM}). The output common-mode feedback circuit 505 is configured to convert the high-voltage common-mode output back to a low-voltage level suitable for being fed into HV driver circuit 506. The reference voltage (V_{REF_OCM}) can be adjusted with reference to the common-mode output current (I_{OCM}) to set the high-voltage differential output voltages (V_{Q1_HV} and V_{Q2_HV}). The common-mode output current (I_{OCM}) passes through a resistive divider, constituted by the pair of third resistors (R₃) 510a-b and the fourth resistor (R₄) 512.

In the absence of any differential input (i.e., V_{Q1_LV}-V_{Q2_LV} equaling zero), the equation

$$2 \times {I}_{OCM} = \frac{{V}_{OCM}}{{R}_{4}}$$

holds. The common-mode output current (I_{OCM}) represents the current that flows from V_{Q1_HV} and V_{Q2_HV} towards the output common-mode voltage (V_{OCM}) through the third resistors (R₃) 510a-b. As the input differential increases, the current flowing from V_{Q1_HV} increases, while the current from V_{Q2_HV} decreases proportionally. These two currents meet at the summing node (i.e., at the output common-mode), where they combine to produce 2×I_{OCM}. The output common-mode feedback circuit 505 forces the output common-mode voltage (V_{OCM}) to maintain equality with the reference voltage (V_{REF_OCM}).

In an exemplary embodiment, the ratio between the second resistors (R₂) 508a-b and the first resisters (R₁) 502a-b equals ten (i.e., R₂/R₁=10×). Assuming that the first differential input (V_{Q1_LV}) equals 2 V and the second differential input (V_{Q2_LV}) equals 1 V—the differential voltage (V_{Q1_LV}-V_{Q2_LV}) equaling 1 V and the common-mode voltage ((V_{Q1_LV}+V_{Q2_LV})/2) equals 1.5 V. In this example, two scenarios are considered based on different selections of the actual output common-mode voltage (V_{OCM_ACTUAL})—the actual output common-mode voltage (V_{OCM_ACTUAL}) being the output common-mode feedback level.

In the first scenario, if the actual output common-mode voltage (V_{OCM_ACTUAL}) is selected to be 7.5 V, then the input voltages (V_{OCM}) to the HV driver circuit 506 equals 0.75V, and the output voltages of the HV driver circuit 506 equals 12.5 V and 2.5 V at each differential output.

In the second scenario, if the actual output common-mode voltage (V_{OCM_ACTUAL}) is selected to be 6 V, then the V_{OCM} input voltages to the HV driver circuit 506 equals 0.6 V, and the output voltages of the HV Driver circuit 506 equals 11 V and 1 V at each differential output.

In each scenario, the actual output common-mode voltage (V_{OCM_ACTUAL}) is considered high-voltage (i.e., greater than gate oxide break down voltage). The output transistors of the HV driver circuit 506 are incapable of operating in the high-voltage domain, as it would lead to gate voltage breakdown. To mitigate this issue and bring the actual output common-mode voltage (V_{OCM_ACTUAL}) down to the low-voltage domain (e.g., less than 4.8 V), an attenuation is performed using resistors third resistors (R₃) 510a-b and the fourth resistor (R₄) 512. This attenuation adjusts the actual output common-mode voltage (V_{OCM_ACTUAL}) to the output common-mode voltage (V_{OCM}), which is within the operating range of the output transistors of the HV driver circuit 506.

The input common-mode feedback circuit 504 separates the input common-mode voltage (V_{ICM}) from the actual output common-mode voltage (V_{OCM_ACTUAL}). The input common-mode current (I_{ICM}) is utilized in the input common-mode feedback circuit 504 feedback mechanism. Additionally, the current (I_{GAIN}) sets the gain at the output of the HV driver circuit 506 in relation to the actual output common-mode voltage (V_{OCM_ACTUAL}).

In embodiments, the common-mode output current (I_{OCM}) is the microamps range for a typical low-power design. In an embodiment, the common-mode output current (I_{OCM}) is less than 1 microamp.

LV-to-HV differential translator circuit 500 operates under a constraint tied to the manufacturing process: the gate oxides within the system are designed to tolerate low-voltage operation, such that the gate-source voltage (V_{GS}) of the gate oxide must not exceed, for example, 4.8 volts to prevent breakdown-a condition that must be avoided. Despite this limitation, LV-to-HV differential translator circuit 500 can utilize a higher drain-source voltage (VDS). Accordingly, LV-to-HV differential translator circuit 500 strategically amplifies a low-voltage input while safeguarding the delicate low-voltage gate oxides from high-voltage outputs.

In the output common-mode feedback circuit 505, the operating voltages can range significantly—for instance, from 14 to 1 volt, creating a 13-volt differential (e.g., V_{OCM} equals 13 V). This could result in a midpoint voltage of 7.5 volts. Without signal attenuation, such a voltage level could be detrimental to the low-voltage gates due to the potential for breakdown. The fourth resistor (R₄) 512 is integrated as an attenuator to achieve signal attenuation. This integration ensures that the common-mode output current (I_{OCM}) flows through the output common-mode feedback circuit 505, providing the necessary attenuation for proper and safe operation of the common-mode voltage (V_{OCM}) within the low-voltage domain.

To achieve stability and prevent mutual interference between the various feedback mechanisms of LV-to-HV differential translator circuit 500, the output common-mode feedback is filtered, and its influence is mitigated relative to the input common-mode feedback. Adjustments to the reference level of the output common-mode feedback circuit 505 allow for modifying the output common-mode voltage (V_{OCM}) while maintaining the differential mode, provided the drive output is not pushed into saturation.

Advantageously, LV-to-HV differential translator circuit 500 predominantly utilizes low-voltage components throughout, limiting high-voltage components at the output stage. This approach enhances overall performance while mitigating potential stresses on low-voltage elements.

In embodiments, the resistance of the first resisters (R₁) 502a-b is in the megaohms range for a typical low-power design. In an embodiment, the resistance of the first resisters (R₁) 502a-b is 600 Kohms.

In embodiments, the resistance of the second resistors (R₂) 508a-b is in the megaohms range for a typical low-power design. In an embodiment, the resistance of the second resistors (R₂) 508a-b is 6000 Kohms.

In embodiments, the resistance of the third resistors (R₃) 510a-b is in the megaohms range for a typical low-power design. In an embodiment, the resistance of the third resistors (R₃) 510a-b is 9000 Kohms.

In embodiments, the resistance of the fourth resistor (R₄) 512 is in the megaohms range for a typical low-power design. In an embodiment, the resistance of the fourth resistor (R₄) 512 is 500 Kohms ohms.

In LV-to-HV differential translator circuit 500, the first voltage (V_{Q1_LV}), the second voltage (V_{Q2_LV}), the output common-mode voltage (V_{OCM}), the reference voltage (V_{REF_ICM}), and the reference voltage (V_{REF_OCM}) are in the low-power voltage domain. In contrast, the first voltage (V_{Q1_HV}) and second voltage (V_{Q2_HV}) are in the high-power voltage domain.

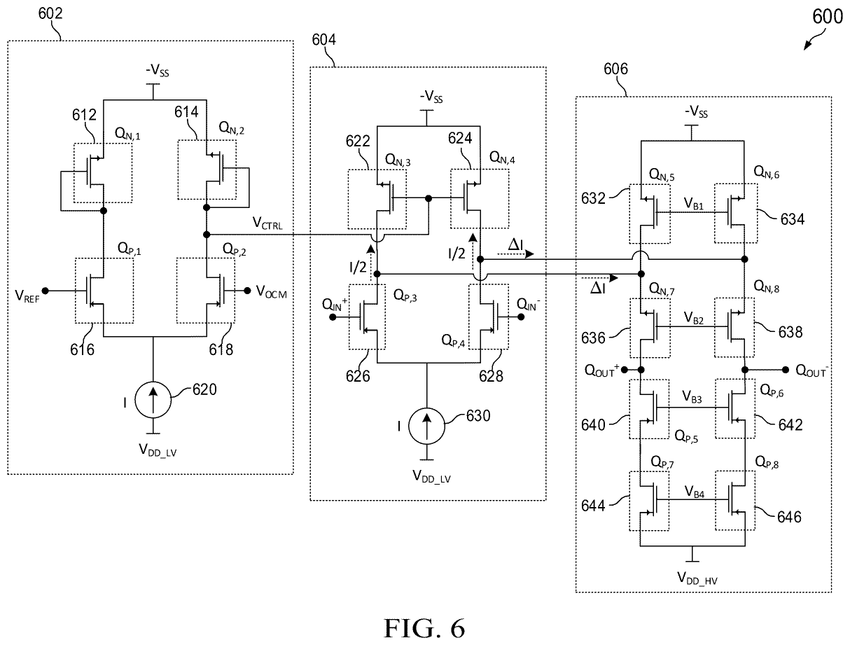

FIG. 6 illustrates a schematic of an embodiment high-voltage (HV) driver circuit 600, which may be implemented as the HV driver circuit 506 in the LV-to-HV differential translator circuit 500. HV driver circuit 600 includes a first stage 602, a second stage 604, and a third stage 606, which may (or may not) be arranged as shown.

In embodiments, each stage may include additional components not shown, such as clamps as a protective feature at various nodes to protect the gate oxide. This clamp can serve as a first line of defense for the device. For example, if an overvoltage or transient condition arises, the clamp is engineered to break down before any other component. Doing so ensures the safety of the gate oxide devices within the transistors, shielding them from potential damage that electrical anomalies could cause.

The first stage 602 includes a first n-channel transistor (Q_{N,1}) 612, a second n-channel transistor (Q_{N,2}) 614, a first p-channel transistor (Q_{P,1}) 616, a second p-channel transistor (Q_{P,2}) 618, and a first current source 620. Each component in the first stage, 602, operates in the low-voltage domain-illustrated by the low-voltage supply (V_{DD_LV}) coupled to the first current source 620.

Each of the first n-channel transistor (Q_{N,1}) 612 and the second n-channel transistor (Q_{N,2}) 614 are arranged in a diode-connected configuration. The source terminal of each of the first n-channel transistor (Q_{N,1}) 612 and the second n-channel transistor (Q_{N,2}) 614 is coupled to the negative voltage source signal (−V_{SS}).

The source terminals of the first p-channel transistor (Q_{P,1}) 616 and the second p-channel transistor (Q_{P,2}) 618 are coupled to the first current source 620. The gate terminal of the first p-channel transistor (Q_{P,1}) 616 is coupled to a reference voltage. The gate terminal of the second p-channel transistor (Q_{P,2}) 618 is coupled to the output common-mode voltage (V_{OCM}).

The drain/gate terminals of the first n-channel transistor (Q_{N,1}) 612 are coupled to the drain terminal of the first p-channel transistor (Q_{P,1}) 616. The drain/gate terminals of the second p-channel transistor (Q_{P,2}) 618 are coupled to the drain terminal of the second p-channel transistor (Q_{P,2}) 618, which provides the control voltage (VCTRL).

The second stage 604 includes a third n-channel transistor (Q_{N,3}) 622, a fourth n-channel transistor (Q_{N,4}) 624, a third p-channel transistor (Q_{P,3}) 626, a fourth p-channel transistor (Q_{P,4}) 628, and a second current source 630. Each of the components in the second stage 604 operate in the low-voltage domain-illustrated by the low-voltage supply (V_{DD_LV}) coupled to the second current source 630.

The source terminals of the third n-channel transistor (Q_{N,3}) 622 and the fourth n-channel transistor (Q_{N,4}) 624 are coupled to the negative voltage source signal (−V_{SS}). The gate terminals of the third n-channel transistor (Q_{N,3}) 622 and the fourth n-channel transistor (Q_{N,4}) 624 are coupled to the output of the first stage 602 and receive the control voltage (VCTRL).

The source terminals of the third p-channel transistor (Q_{P,3}) 626 and the fourth p-channel transistor (Q_{P,4}) 628 are coupled to the second current source 630. The gate terminal of the third p-channel transistor (Q_{P,3}) 626 is coupled to the input voltage (Q_{IN}_{⁺}). The gate terminal of the fourth p-channel transistor (Q_{P,4}) 628 is coupled to the input voltage (Q_{IN}_{^{−}}).

The drain of the third n-channel transistor (Q_{N,3}) 622 is coupled to the drain terminal of the third p-channel transistor (Q_{P,3}) 626, which provides a first signal to the third stage 606. The drain of the fourth n-channel transistor (Q_{N,4}) 624 is coupled to the drain terminal of the fourth p-channel transistor (Q_{P,4}) 628, which provides a second signal to the third stage 606.

The third stage 606 is a folded stage due to the p-channel input differential pairs fed to an n-channel cascode. The third stage 606 includes a fifth n-channel transistor (Q_{N,5}) 632, a sixth n-channel transistor (Q_{N,6}) 634, a seventh n-channel transistor (Q_{N,7}) 636, an eight n-channel transistor (Q_{N,8}) 638, a fifth p-channel transistor (Q_{P,5}) 640, a sixth p-channel transistor (Q_{P,6}) 642, a seventh p-channel transistor (Q_{P,7}) 644, and an eight p-channel transistor (Q_{P,8}) 646.

The source terminals of the fifth n-channel transistor (Q_{N,5}) 632 and the sixth n-channel transistor (Q_{N,6}) 634 are coupled to the negative voltage source signal (−V_{SS}). The gate terminals of the fifth n-channel transistor (Q_{N,5}) 632 and the sixth n-channel transistor (Q_{N,6}) 634 are coupled at the first shared node (V_{B1}). The drain terminal of the fifth n-channel transistor (Q_{N,5}) 632 is coupled to the drain terminal of the third n-channel transistor (Q_{N,3}) 622, which receives the first signal from the second stage 604. The drain terminal of the sixth n-channel transistor (Q_{N,6}) 634 is coupled to the drain terminal of the fourth n-channel transistor (Q_{N,4}) 624, which receives the second signal from the second stage 604.

The source terminal of the seventh n-channel transistor (Q_{N,7}) 636 is coupled to the drain terminal of the fifth n-channel transistor (Q_{N,5}) 632. The source terminal of the eight n-channel transistor (Q_{N,8}) 638 is coupled to the drain terminal of the sixth n-channel transistor (Q_{N,6}) 634. The gate terminals of the seventh n-channel transistor (Q_{N,7}) 636 and the eight n-channel transistor (Q_{N,8}) 638 are coupled at the second shared node (V_{B2}). The drain terminal of the seventh n-channel transistor (Q_{N,7}) 636 provides the output voltage (Q_{OUT}_{⁺}). The drain terminal of the eight n-channel transistor (Q_{N,8}) 638 provides the output voltage (Q_{OUT}_{^{−}}). In embodiments, a low-voltage clamp is coupled to the drain terminals of the seventh n-channel transistor (Q_{N,7}) 636 and the eight n-channel transistor (Q_{N,8}) 638 to protect the gate oxide of the low-voltage domain devices.

The drain terminal of the fifth p-channel transistor (Q_{P,5}) 640 is coupled to the drain terminal of the seventh n-channel transistor (Q_{N,7}) 636. The drain terminal of the sixth p-channel transistor (Q_{P,6}) 642 is coupled to the drain terminal of the eight n-channel transistor (Q_{N,8}) 638. The gate terminals of the fifth p-channel transistor (Q_{P,5}) 640 and the sixth p-channel transistor (Q_{P,6}) 642 are coupled at the third shared node (V_{B3}). In embodiments, a low-voltage clamp is coupled to the third shared node (V_{B3}) to protect the gate oxide of the low-voltage domain devices.

The drain terminal of the seventh p-channel transistor (Q_{P,7}) 644 is coupled to the drain terminal of the fifth p-channel transistor (Q_{P,5}) 640. The drain terminal of the eight p-channel transistor (Q_{P,8}) 646 is coupled to the drain terminal of the sixth p-channel transistor (Q_{P,6}) 642. The gate terminals of the seventh p-channel transistor (Q_{P,7}) 644 and the eight p-channel transistor (Q_{P,8}) 646 are coupled at the fourth shared node (V_{B4}). The source terminals of the seventh p-channel transistor (Q_{P,7}) 644 and the eight p-channel transistor (Q_{P,8}) 646 are coupled to a high-voltage supply (V_{DD_HV}). In embodiments, a low-voltage clamp is coupled to the fourth shared node (V_{B4}) to protect the gate oxide of the low-voltage domain devices.

The fifth n-channel transistor (Q_{N,5}) 632 and the sixth n-channel transistor (Q_{N,6}) 634 form a current mirror circuit and operate in the low-voltage domain. The fifth n-channel transistor (Q_{N,5}) 632 and the sixth n-channel transistor (Q_{N,6}) 634 are configured for matching with a low-noise and small footprint characteristic.

The fifth p-channel transistor (Q_{P,5}) 640 and the sixth p-channel transistor (Q_{P,6}) 642 form a cascode current source—operating in the high-voltage domain—to protect the seventh p-channel transistor (Q_{P,7}) 644 and the eight p-channel transistor (Q_{P,8}) 646 that form a current mirror circuit in the low-voltage domain. The seventh p-channel transistor (Q_{P,7}) 644 and the eight p-channel transistor (Q_{P,8}) 646 are configured for matching with a low-noise and small footprint characteristic.

The first stage 602 is configured to stabilize and regulate the output common-mode. The first stage 602 provides a control voltage (VCTRL), which can be represented by the equation: V_{CTRL}=−gₘ×ΔV_{OCM}×r_{D}, where gₘ is the transconductance of the differential transistor pair of first p-channel transistor (Q_{P,1}) 616 and the second p-channel transistor (Q_{P,2}) 618, ΔV_{OCM} is the voltage variation of the output common-mode voltage (i.e., ΔV_{OCM}=V_{OCM}−V_{REF}), and r_{D} is the dynamic resistance of the first n-channel transistor (Q_{N,1}) 612 and the second n-channel transistor (Q_{N,2}) 614. If ΔV_{OCM} is greater than zero, the variation of the control voltage (V_{CTRL}) is negative, resulting in the third n-channel transistor (Q_{N,3}) 622 and the fourth n-channel transistor (Q_{N,4}) 624 draining less current, and a positive variation of the current (ΔI) flows from the second stage 604 to the third stage 606.

The second stage 604 is configured to regulate the differential mode and provide the high-voltage gain, the high-voltage level shifting, or a combination thereof.

In a balanced system, the current flowing through the fourth n-channel transistor (Q_{N,4}) 624 and the sixth n-channel transistor (Q_{N,6}) 634 is equal to half of the total current (I/2) plus the current flowing through the eight p-channel transistor (Q_{P,8}) 646. The current through the third n-channel transistor (Q_{N,3}) 622 and the fourth n-channel transistor (Q_{N,4}) 624 acts as a mirror to that of the second n-channel transistor (Q_{N,2}) 614. The output common-mode feedback influences the output common-mode voltage (V_{OCM}) to regulate to a reference voltage (V_{REF}), which adjusts the current through the second n-channel transistor (Q_{N,2}) 614. This regulation of current through the second n-channel transistor (Q_{N,2}) 614 results in corresponding positive and negative changes in current (+ΔI, −ΔI), which then controls the negative and positive output voltages (Q_{OUT}_{⁺} and Q_{OUT}_{^{−}}).

A differential gain exists between the input voltages (V_{Q1_LV} and V_{Q2_LV}) and the output voltages (Q_{OUT}_{⁺} and Q_{OUT}_{^{−}}). This differential gain is achieved through the first resisters (R₁) 502a-b to the second resistors (R₂) 508a-b, positioned externally to the HV driver circuit 600—as shown in FIG. 5.

A common-mode gain exists between the reference voltage (V_{REF}) and the output common-mode voltage (V_{OCM}). This common-mode gain is attained by virtue of the third resistors (R₃) 510a-b and the fourth resistor (R₄) 512, positioned externally to the HV driver circuit 600—as shown in FIG. 5.

In embodiments, the HV driver circuit 600 includes a class A output stage, which acts as a gain stage, although this is not depicted in the diagrams. Within this Class A output stage, the current mirrors are comprised of two key components: an n-channel transistor cascode device that operates in the high-voltage domain and a current mirror bias device that functions in the low-voltage domain. These two elements form the current mirrors for the Class A output stage's operation.

The seventh n-channel transistor (Q_{N,7}) 636, the eight n-channel transistor (Q_{N,8}) 638, the fifth p-channel transistor (Q_{P,5}) 640, and the sixth p-channel transistor (Q_{P,6}) 642 transistors operate in the high-voltage domain and form cascodes to protect the low-voltage domain devices.

A first aspect relates to a circuit for correcting a quadrature error in a gyroscope. The circuit comprising: a pair of first resistors configured to receive a differential input low-voltage signal, a differential value of the differential input low-voltage signal set based on a demodulated quadrature signal measured by sense electrodes of the gyroscope; an input common-mode feedback (ICMFB) circuit coupled to the pair of first resistors, the ICMFB circuit comprising a pair of adjustable current sinks configured to regulate an input common-mode of the circuit at a low-voltage level by managing current flowing through the adjustable current sinks; a high-voltage (HV) driver circuit configured to provide a differential output high-voltage signal based on the differential input low-voltage signal, the differential output high-voltage signal being fed to quadrature correction electrodes of the gyroscope to correct the quadrature error; a pair of second resistors, wherein a differential gain between the input differential input low-voltage signal and the differential output high-voltage signal is determined by a relative resistance values of the pair of first resistors and pair of second resistors; and an output common-mode feedback circuit configured to convert a high-voltage common-mode output of the circuit to a low-voltage level suitable for the HV driver circuit.

In a first implementation form of the circuit, according to the first aspect as such, the ICMFB circuit further comprises a differential amplifier having a first input coupled to a reference voltage, the differential amplifier configured to provide a control signal based on the reference voltage to each of the adjustable current sinks to manage current flowing through the adjustable current sinks; and an adder circuit configured to combine a non-inverting and an inverting signal of the differential input low-voltage signal, an output of the adder circuit coupled to a second input of the differential amplifier.

In a second implementation form of the circuit, according to the first aspect as such or any preceding implementation form of the first aspect, the OCMFB circuit comprises a pair of third resistors and a fourth resistor forming a resistor divider, wherein the resistor divider is configured to attenuate the high-voltage level at the output of the HV driver circuit to the low-voltage level suitable for the HV driver circuit.

In a third implementation form of the circuit, according to the first aspect as such or any preceding implementation form of the first aspect, the OCMFB further comprises a differential amplifier having a first input terminal coupled to a shared node between the third resistors and the fourth resistor, a second input terminal of the differential amplifier coupled to a reference voltage, the differential amplifier configured to provide a low-voltage signal to the HV driver circuit based on a difference between a output common-mode voltage of the circuit and the reference voltage.

In a fourth implementation form of the circuit, according to the first aspect as such or any preceding implementation form of the first aspect, the HV driver circuit comprises a folded cascode operational amplifier with a class A output stage and a common-mode feedback circuit.

In a fifth implementation form of the circuit, according to the first aspect as such or any preceding implementation form of the first aspect, the HV driver circuit comprises a first low-voltage stage, a second low-voltage stage, and a third high-voltage stage.

In a sixth implementation form of the circuit, according to the first aspect as such or any preceding implementation form of the first aspect, the HV driver circuit further comprises a class A output stage.

A second aspect relates to system for correcting a quadrature error in a gyroscope, the system comprising: a digital control circuit configured to generate a differential input low-voltage signal based on a demodulated quadrature signal from sense electrodes of the gyroscope; and a low-voltage to high-voltage (LV-to-HV) differential translator circuit, the LV-to-HV differential translator circuit comprising: a pair of first resistors configured to receive the differential input low-voltage signal, an input common-mode feedback (ICMFB) circuit coupled to the pair of first resistors, the ICMFB circuit comprising a pair of adjustable current sinks configured to regulate an input common-mode of the LV-to-HV differential translator circuit at a low-voltage level by managing current flowing through the adjustable current sinks, a high-voltage (HV) driver circuit configured to provide a differential output high-voltage signal based on the differential input low-voltage signal, the differential output high-voltage signal being fed to quadrature correction electrodes of the gyroscope to correct the quadrature error, a pair of second resistors, wherein a differential gain between the input differential input low-voltage signal and the differential output high-voltage signal is determined by a relative resistance values of the pair of first resistors and pair of second resistors, and an output common-mode feedback circuit configured to convert a high-voltage common-mode output of the LV-to-HV differential translator circuit to a low-voltage level suitable for the HV driver circuit.

In a first implementation form of the system, according to the second aspect as such, the system further includes the gyroscope.

In a second implementation form of the system, according to the second aspect as such or any preceding implementation form of the second aspect, the ICMFB circuit further comprises a differential amplifier having a first input coupled to a reference voltage, the differential amplifier configured to provide a control signal based on the reference voltage to each of the adjustable current sinks to manage current flowing through the adjustable current sinks; and an adder circuit configured to combine a non-inverting and an inverting signal of the differential input low-voltage signal, an output of the adder circuit coupled to a second input of the differential amplifier.

In a third implementation form of the system, according to the second aspect as such or any preceding implementation form of the second aspect, the OCMFB circuit comprises a pair of third resistors and a fourth resistor forming a resistor divider, wherein the resistor divider is configured to attenuate the high-voltage level at the output of the HV driver circuit to the low-voltage level suitable for the HV driver circuit.

In a fourth implementation form of the system, according to the second aspect as such or any preceding implementation form of the second aspect, the OCMFB further comprises a differential amplifier having a first input terminal coupled to a shared node between the third resistors and the fourth resistor, a second input terminal of the differential amplifier coupled to a reference voltage, the differential amplifier configured to provide a low-voltage signal to the HV driver circuit based on a difference between a output common-mode voltage of the circuit and the reference voltage.

In a fifth implementation form of the system, according to the second aspect as such or any preceding implementation form of the second aspect, the HV driver circuit comprises a folded cascode operational amplifier with a class A output stage and a common-mode feedback circuit.

In a sixth implementation form of the system, according to the second aspect as such or any preceding implementation form of the second aspect, the HV driver circuit comprises a first low-voltage stage, a second low-voltage stage, and a third high-voltage stage.

A third aspect relates to a system to correct a quadrature error in a gyroscope, the system comprising: a digital control circuit configured to generate a differential input low-voltage signal based on a demodulated quadrature signal from sense electrodes of the gyroscope; and a low-voltage to high-voltage (LV-to-HV) differential translator circuit configured to receive the differential input low-voltage signal and generate a differential output low-voltage signal for quadrature correction electrodes of the gyroscope to correct the quadrature error, the LV-to-HV differential translator circuit comprising: an input common-mode feedback (ICMFB) circuit configured to regulate an input common-mode of the LV-to-HV differential translator circuit at a low-voltage level, a high-voltage (HV) driver circuit configured to provide the differential output high-voltage signal based on the differential input low-voltage signal, and an output common-mode feedback circuit configured to convert a high-voltage common-mode output of the LV-to-HV differential translator circuit to a low-voltage level suitable for the HV driver circuit.

In a first implementation form of the system, according to the third aspect as such, the ICMFB circuit comprises: a pair of adjustable current sinks; a differential amplifier having a first input coupled to a reference voltage, the differential amplifier configured to provide a control signal based on the reference voltage to each of the adjustable current sinks to manage current flowing through the adjustable current sinks; and an adder circuit configured to combine a non-inverting and an inverting signal of the differential input low-voltage signal, an output of the adder circuit coupled to a second input of the differential amplifier.

In a second implementation form of the system, according to the third aspect as such or any preceding implementation form of the third aspect, the OCMFB circuit comprises a pair of third resistors and a fourth resistor forming a resistor divider, wherein the resistor divider is configured to attenuate the high-voltage level at the output of the HV driver circuit to the low-voltage level suitable for the HV driver circuit.

In a third implementation form of the system, according to the third aspect as such or any preceding implementation form of the third aspect, the OCMFB further comprises a differential amplifier having a first input terminal coupled to a shared node between the third resistors and the fourth resistor, a second input terminal of the differential amplifier coupled to a reference voltage, the differential amplifier configured to provide a low-voltage signal to the HV driver circuit based on a difference between a output common-mode voltage of the circuit and the reference voltage.

In a fourth implementation form of the system, according to the third aspect as such or any preceding implementation form of the third aspect, the HV driver circuit comprises a folded cascode operational amplifier with a class A output stage and a common-mode feedback circuit.

In a fifth implementation form of the system, according to the third aspect as such or any preceding implementation form of the third aspect, the HV driver circuit comprises a first low-voltage stage, a second low-voltage stage, and a third high-voltage stage.

Although the description has been described in detail, it should be understood that various changes, substitutions, and alterations may be made without departing from the spirit and scope of this disclosure as defined by the appended claims. The same elements are designated with the same reference numbers in the various figures. Moreover, the scope of the disclosure is not intended to be limited to the particular embodiments described herein, as one of ordinary skill in the art will readily appreciate from this disclosure that processes, machines, manufacture, compositions of matter, means, methods, or steps, presently existing or later to be developed, may perform substantially the same function or achieve substantially the same result as the corresponding embodiments described herein. Accordingly, the appended claims are intended to include within their scope such processes, machines, manufacture, compositions of matter, means, methods, or steps.

The specification and drawings are, accordingly, to be regarded simply as an illustration of the disclosure as defined by the appended claims, and are contemplated to cover any and all modifications, variations, combinations, or equivalents that fall within the scope of the present disclosure.

What is claimed is:

1. A circuit for correcting a quadrature error in a gyroscope, the circuit comprising:
a pair of first resistors configured to receive a differential input low-voltage signal, a differential value of the differential input low-voltage signal set based on a demodulated quadrature signal measured by sense electrodes of the gyroscope;
an input common-mode feedback (ICMFB) circuit coupled to the pair of first resistors, the ICMFB circuit comprising a pair of adjustable current sinks configured to regulate an input common-mode of the circuit at a low-voltage level by managing current flowing through the adjustable current sinks;
a high-voltage (HV) driver circuit configured to provide a differential output high-voltage signal based on the differential input low-voltage signal, the differential output high-voltage signal being fed to quadrature correction electrodes of the gyroscope to correct the quadrature error;
a pair of second resistors, wherein a differential gain between the input differential input low-voltage signal and the differential output high-voltage signal is determined by a relative resistance values of the pair of first resistors and pair of second resistors; and
an output common-mode feedback circuit configured to convert a high-voltage common-mode output of the circuit to a low-voltage level suitable for the HV driver circuit.

2. The circuit of claim 1, wherein the ICMFB circuit further comprises:
a differential amplifier having a first input coupled to a reference voltage, the differential amplifier configured to provide a control signal based on the reference voltage to each of the adjustable current sinks to manage current flowing through the adjustable current sinks; and
an adder circuit configured to combine a non-inverting and an inverting signal of the differential input low-voltage signal, an output of the adder circuit coupled to a second input of the differential amplifier.

3. The circuit of claim 1, wherein the OCMFB circuit comprises a pair of third resistors and a fourth resistor forming a resistor divider, wherein the resistor divider is configured to attenuate the high-voltage level at the output of the HV driver circuit to the low-voltage level suitable for the HV driver circuit.

4. The circuit of claim 3, wherein the OCMFB circuit further comprises a differential amplifier having a first input terminal coupled to a shared node between the third resistors and the fourth resistor, a second input terminal of the differential amplifier coupled to a reference voltage, the differential amplifier configured to provide a low-voltage signal to the HV driver circuit based on a difference between a output common-mode voltage of the circuit and the reference voltage.

5. The circuit of claim 1, wherein the HV driver circuit comprises a folded cascode operational amplifier with a class A output stage and a common-mode feedback circuit.

6. The circuit of claim 1, wherein the HV driver circuit comprises a first low-voltage stage, a second low-voltage stage, and a third high-voltage stage.

7. The circuit of claim 6, wherein the HV driver circuit further comprises a class A output stage.

8. A system for correcting a quadrature error in a gyroscope, the system comprising:
a digital control circuit configured to generate a differential input low-voltage signal based on a demodulated quadrature signal from sense electrodes of the gyroscope; and
a low-voltage to high-voltage (LV-to-HV) differential translator circuit, the LV-to-HV differential translator circuit comprising:
a pair of first resistors configured to receive the differential input low-voltage signal,
an input common-mode feedback (ICMFB) circuit coupled to the pair of first resistors, the ICMFB circuit comprising a pair of adjustable current sinks configured to regulate an input common-mode of the LV-to-HV differential translator circuit at a low-voltage level by managing current flowing through the adjustable current sinks,
a high-voltage (HV) driver circuit configured to provide a differential output high-voltage signal based on the differential input low-voltage signal, the differential output high-voltage signal being fed to quadrature correction electrodes of the gyroscope to correct the quadrature error,
a pair of second resistors, wherein a differential gain between the input differential input low-voltage signal and the differential output high-voltage signal is determined by a relative resistance values of the pair of first resistors and pair of second resistors, and
an output common-mode feedback circuit configured to convert a high-voltage common-mode output of the LV-to-HV differential translator circuit to a low-voltage level suitable for the HV driver circuit.

9. The system of claim 8, further comprising the gyroscope.

10. The system of claim 8, wherein the ICMFB circuit further comprises:
a differential amplifier having a first input coupled to a reference voltage, the differential amplifier configured to provide a control signal based on the reference voltage to each of the adjustable current sinks to manage current flowing through the adjustable current sinks; and
an adder circuit configured to combine a non-inverting and an inverting signal of the differential input low-voltage signal, an output of the adder circuit coupled to a second input of the differential amplifier.

11. The system of claim 8, wherein the OCMFB circuit comprises a pair of third resistors and a fourth resistor forming a resistor divider, wherein the resistor divider is configured to attenuate the high-voltage level at the output of the HV driver circuit to the low-voltage level suitable for the HV driver circuit.

12. The system of claim 11, wherein the OCMFB further comprises a differential amplifier having a first input terminal coupled to a shared node between the third resistors and the fourth resistor, a second input terminal of the differential amplifier coupled to a reference voltage, the differential amplifier configured to provide a low-voltage signal to the HV driver circuit based on a difference between a output common-mode voltage of the circuit and the reference voltage.

13. The system of claim 8, wherein the HV driver circuit comprises a folded cascode operational amplifier with a class A output stage and a common-mode feedback circuit.

14. The system of claim 8, wherein the HV driver circuit comprises a first low-voltage stage, a second low-voltage stage, and a third high-voltage stage.

15. A system to correct a quadrature error in a gyroscope, the system comprising:
a digital control circuit configured to generate a differential input low-voltage signal based on a demodulated quadrature signal from sense electrodes of the gyroscope; and
a low-voltage to high-voltage (LV-to-HV) differential translator circuit configured to receive the differential input low-voltage signal and generate a differential output low-voltage signal for quadrature correction electrodes of the gyroscope to correct the quadrature error, the LV-to-HV differential translator circuit comprising:
an input common-mode feedback (ICMFB) circuit configured to regulate an input common-mode of the LV-to-HV differential translator circuit at a low-voltage level,
a high-voltage (HV) driver circuit configured to provide the differential output high-voltage signal based on the differential input low-voltage signal, and
an output common-mode feedback circuit configured to convert a high-voltage common-mode output of the LV-to-HV differential translator circuit to a low-voltage level suitable for the HV driver circuit.

16. The system of claim 15, wherein the ICMFB circuit comprises:
a pair of adjustable current sinks;
a differential amplifier having a first input coupled to a reference voltage, the differential amplifier configured to provide a control signal based on the reference voltage to each of the adjustable current sinks to manage current flowing through the adjustable current sinks; and
an adder circuit configured to combine a non-inverting and an inverting signal of the differential input low-voltage signal, an output of the adder circuit coupled to a second input of the differential amplifier.

17. The system of claim 15, wherein the OCMFB circuit comprises a pair of third resistors and a fourth resistor forming a resistor divider, wherein the resistor divider is configured to attenuate the high-voltage level at the output of the HV driver circuit to the low-voltage level suitable for the HV driver circuit.

18. The system of claim 17, wherein the OCMFB further comprises a differential amplifier having a first input terminal coupled to a shared node between the third resistors and the fourth resistor, a second input terminal of the differential amplifier coupled to a reference voltage, the differential amplifier configured to provide a low-voltage signal to the HV driver circuit based on a difference between a output common-mode voltage of the circuit and the reference voltage.

19. The system of claim 15, wherein the HV driver circuit comprises a folded cascode operational amplifier with a class A output stage and a common-mode feedback circuit.

20. The system of claim 15, wherein the HV driver circuit comprises a first low-voltage stage, a second low-voltage stage, and a third high-voltage stage.
